(19) United States
(12) Patent Application Publication
(10) Pub. No.: US 2007/0087469 A1
(43) Pub. Date: Apr. 19, 2007

(54) Particulate for organic and inorganic light active devices and methods for fabricating the same

(75) Inventor: John J. Daniels, Madison, CT (US)

Correspondence Address: MICHAUD-DUFFY GROUP LLP, 306 INDUSTRIAL PARK ROAD, SUITE 206, MIDDLETOWN, CT, 06457, US

(73) Assignee: Articulated Technologies, LLC, Higganum, CT (US)

(21) Appl. No.: 11/527,212

(22) Filed: Sep. 25, 2006

Related U.S. Application Data
(62) Division of application No. 10/871,398, filed on Jun. 21, 2004.

(51) Int. Cl. H01L 51/40; H01L 21/00

(52) U.S. Cl. 438/99; 438/28

(57) ABSTRACT

A method of making polymer blend light active particles, comprising the steps of providing a solution comprised of a first organic light active diode material and a second organic light active diode material in a solvent and providing a non-solvent liquid. The method of making polymer blend light active particles also includes the step of adding the solution to the non-solvent liquid to cause a precipitation reaction resulting in multi-layered particles comprising the first and second organic light active diode materials. A method of making a light active electronic device, comprising the steps of providing at least one of organic and inorganic light active particles in a non-solvent liquid; adding a charge transport carrier polymer to the non-solvent liquid to form a fluid carrier/particle mixture; and disposing the mixture between electrodes to form a light active electronic device.

### CROSS REFERENCE TO RELATED APPLICATIONS

This patent application is a divisional application of and claims the benefit under 35 U.S.C. §120 of U.S. patent application Ser. No. 10/871,398, filed Jun. 21, 2004. This application relates to co-pending U.S. Utility patent application Ser. No. 10/375,728, entitled “Organic Light Devices with Particulated Light Active Material in a Carrier Matrix,” filed Feb. 26, 2003.

### BACKGROUND

The present invention relates nano-particulate for organic and inorganic light generating devices. More particularly, the present invention relates to solid-state organic and inorganic light generating devices having nano-particulate emissive point sources and methods of fabricating the same.

Reducing the consumption of energy is a long standing national objective. A recent study by the US Department of Energy shows that 7.2 Quads (quadrillions of British Thermal Units—BTUs) were consumed in 2001 to provide commercial and residential lighting in the USA. About 20% of all the electricity produced in the US goes to illumination, and only 30% of this energy is used to actually generate light. The rest is wasted as heat (see, J. R. Brodrick, OIDA OLED Workshop, Apr. 5, 2002; Source: U.S. Lighting Market Characterization, Volume 1—Lighting Inventory and Energy Consumption Estimate, Draft for Review, Arthur D. Little, Arlington, Va., Mar. 5, 2002.). Incandescent lights are less than 10% efficient—over 90% of the energy is converted to heat. Fluorescent lighting is more efficient, but has environmental costs and still wastes a lot of energy. There has not been much progress made in the efficiency of these conventional sources of light within the past 30-50 years, and these technologies have reached their technical maturity, so it is not likely that they will ever be made more efficient.

Solid-state lighting (SSL), on the other hand, has the promise of much better energy-to-light conversion efficiencies than the conventional light sources. Organic light active diode (OLED) is a very exciting new SSL technology that operates at low voltages of around 3-5V. OLEDs have the potential of being large area, white light sources that are bright, power-efficient, ultra-thin, lightweight, durable and inexpensive. They can be made flexible, and open the possibility of new form factors that take advantage of their lightweight and extreme thinness. With the proper packaging and ancillary electronics, they can be adapted to pre-existing form factors, such as light-bulb sockets. OLEDs can eventually replace distributed light sources, such as fluorescent and incandescent lamps. If a suitable device structure and manufacturing method can be developed, OLEDs will also create new lighting forms, such as large area illumination configurations for ceilings, walls, rugs, and fabric.

It has been estimated that OLED SSL could save the US over $25 billion per year in energy savings. In addition to the direct energy cost savings, there would be less heat generated that needs to be removed from offices and homes during warm weather, saving on air conditioning costs. There would be less new energy plant infrastructure needed, saving construction and maintenance costs. Less energy consumed would result in less pollution of water and air.

In addition to the reduced pollution and energy cost savings associated with the use of SSL OLED lighting, the public will also benefit from the new lighting form factors that can be obtained by the very thin OLED lighting panels. For example, drop ceilings will no longer be needed to bring lighting to newly finished rooms. Walls, floors and ceilings can be covered with continuous lighting sources in the form of wallpaper, floor coverings and thin light panels, reducing shadows and providing a more consistent and pleasing light. The OLED emitted light color and brightness can be adjusted to provide a more soothing and appealing room light. The new form factors, light colors and the continuous light emission available will lend OLED lighting to many new, advantageous applications and effects.

In an OLED device, electrons are injected into the conduction band of an organic material and holes are injected into the valence band. The carriers diffuse across the organic material until they meet and recombine forming excitons. The excitons radiatively decay, producing photon emissions, or light. In basic terms, a hole transport layer conveys holes to the recombination site, and an electron transport layer conveys electrons to the recombination site. In a practical device, the energy difference between the electrode and the charge generation layer may require another layer, such as a hole blocking layer, to facilitate charge injection and reduce the operating voltage (See, for example, S. A. Van Slyke, C. H. Chen, and C. W. Tang, Appl. Phys. Lett., 69, 2160 (1996)).

Practical OLED materials have been around since the late 1980's when researchers at Kodak invented a double layer “small molecule” device that operated at low voltage (<10 v) with good brightness (>1000 cd/m²)(see, ¹C. W. Tang, S. A. Van Slyke, C. H. Chen, Appl. Phys. Lett. 65, 3610 (1989)). Over a decade ago it was shown that conjugated polymers could be made to be electroluminescent (see, J. H. Burroughtes et al., Nature 347, 539 (1990)). Since then there has been a very rapid advancement in the creation of new OLED material compounds. Thousands of effective OLED material compositions have already been made. Because they are organic compounds, the opportunities for advancements in the material science of OLEDs is nearly endless. Already, researchers have made “good quality” white light OLED devices.

It has been shown that energy efficient triplet excitons can be used to generate white light by an OLED device comprised of three emissive layers. By precisely controlling the thickness and composition of each layer, a color balance is obtained to generate the desired white light. The relative emission intensity can be controlled by varying doping concentrations, controlling each layer thickness and including an exciton blocking layer (see, P. E. Burrows, S. R. Sibley, and M. E. Thompson, Appl. Phys. Lett., 69, 2959 (1996)). While effective for producing the desired white light, this example indicates the complexity necessary to obtain a practical OLED light source. It has proven extremely difficult to obtain the precise film thickness, the multi-layered organic stack structure, and the preservation of the sensitive organic films using the available OLED fabrication techniques.

As an example of the endless possibilities provided through organic cheaerosolry, researchers have designed iridium-based emitters that cover the entire chromaticity spectrum (see, OIDA OLEDs update 2002, FIG. 14, page 32). Both small-molecule and polymeric systems with singlet (fluorescence) emitters have achieved white color by mixing colors with narrow band spectra. Recent progress in obtaining triplet (phosphorescence) emitters will lead to increased efficiencies and a greater selection of colors. There seems to be little in the way, cheaerosolry-wise, to the fulfillment of the promise of OLEDs as a highly efficient, durable, cost effective light source for the 21^{st} Century and beyond.

However, the potential of OLED lighting is being held back because there is still no suitable fabrication technology. The conventional OLED fabrication technologies all suffer from the same major drawback, the need to form and preserve extremely thin films of highly sensitive organic materials.

Over time, OLED researchers have improved properties such as power efficiencies, color spectrum, and long-term reliability. But, virtually every commercial development thus far has evolved from high technology/semiconductor-type manufacturing, i.e.—requiring clean rooms, involving vacuum deposition/spin coating of thin films in conjunction with the use of rigid substrates. High technology manufacturing techniques applied towards the production of conventional thin-film OLED devices have proven inherently difficult to achieve useful light sources. Newer technologies based on ink jet printing techniques are evolving and hold promise for expanding the horizons of OLED devices. Yet significant issues, not the least being cost, remain to be overcome before OLED device fabrication based upon ink jet printing becomes a commercial reality. The major technological challenges facing manufacturers of thin film OLED devices have been:
Oxygen and moisture susceptibility of the organic layers.
The permeability of the substrate materials (other than glass) to oxygen and water.
Achieving surface smoothness/conformability of the applied layers and electrodes.
Selecting solvent systems that allow additional film layers added to not dissolve or degrade layers that already have been applied.
Preventing dust contamination of the thin films which cause electrical shorts between the electrodes
   The present invention is to the nano-particulate for use in an OLED composite film comprised of the OLED nano-particles dispersed within a protective electron carrier matrix. This novel device architecture makes practical large-scale manufacturing. The result is an OLED device having superior performance characteristics, with a much simplified layer structure, as compared with any of the currently available OLED light designs. The resulting OLED particulate/matrix device structure avoids the drawbacks of all other OLED fabrication methods, including spin coated, inkjet and vacuum deposited ultra thin organic films. Using commercially available plastic substrate material, the inventive device structure does not require additional encapsulation, and has excellent resistance to deleterious effects due to oxygen and moisture attack on the polymeric components within the OLED structure. Notably, the inventive system works with both small molecule and polymeric OLED materials, and/or a combination of organic and inorganic emitters.

A survey of the relevant patent literature shows that many researchers are addressing the issues that pertain to making ultra-thin film OLED devices. In most cases, these researchers are contributing incremental advancements in an attempt to overcome the inherent problems associated with the formation and preservation of ultra-thin organic films disposed between conductive electrodes. As an example of an OLED device, U.S. Pat. No. 5,247,190 issued to Friend et al., teaches an electroluminescent device comprising a semiconductor layer in the form of a thin dense polymer film comprising at least one conjugated polymer sandwiched between two contact layers that inject holes and electrons into the thin polymer film. The injected holes and electrons result in the emission of light from the thin polymer film.

Typically, the organic materials are deposited by solution processing such as spin-coating, by vacuum deposition or evaporation. As examples, U.S. Pat. No. 6,395,328, issued to May, teaches an organic light emitting color light panel wherein a multi-color device is formed by depositing and patterning thin layers of light emissive material. U.S. Pat. No. 5,965,979, issued to Friend, et al., teaches a method of making a light emitting device by laminating two self-supporting components. U.S. Pat. No. 6,087,196, issued to Strum, et al., teaches forming organic semiconductor devices using ink jet printing. U.S. Pat. 6,420,200 B1, issued to Yamazaki et al., teaches a method of manufacturing an electro-optical device using a relief printing or screen printing method for printing thin layers of electro-optical material. U.S. Pat. No.6,402,579 B1, issued to Pichler et al., teaches an organic light-emitting device in which a multi-layer structure is formed by DC magnetron sputtering to form multiple thin layers of organic light emitting material.

Other examples of OLED devices described in the patent literature include U.S. Pat. No. 5,858,561, issued to Epstein et al. This reference teaches a light emitting bipolar-device consisting of a thin layer of organic light emitting material sandwiched between two layers of insulating material. The device can be operated with AC voltage or DC voltage. U.S. Pat. No. 6,433,355 B1, issued to Riess et al., teaches an organic light emitting device wherein a thin organic film region is disposed between an anode electrode and a cathode electrode, at least one of the electrodes comprises a non-degenerate wide band-gap semiconductor to improve the operating characteristic of the light emitting device.

These references all tend to indicate incremental advancements in the OLED technology. The present invention, in contrast, may represent a true breakthrough in the fabrication and structure of OLED light devices, making possible the near-term deployment of such devices as energy efficient products for residential and commercial lighting applications.

Researchers throughout the world are exploring the potential of a good quality OLED white light sources. For example, it has been shown that white light can be generated from a blue light emitting organic bilayer device. The device was made by consecutive vacuum deposition of two newly discovered organic emitters that produce light in the blue region. The organic material is deposited on ITO coated glass, followed by vacuum deposited Al—Li alloy cathode (see, ¹A field-dependent organic LED consisting of two new high T blue light emitting organic layers: a possibility of attainment of a white light sthe inventivece. Soon Wook Cha and Jung-Il Jin, J Mater Chem, 2003, 13, 3, 479.).

Others have shown that a single organic emitting layer can produce white light. In this case, a blue host material SAlq is doped with a red fluorescent dye DCJTB and vapor deposited on ITO coated glass. The incomplete energy transfer from the blue emitter to the red dye enables a stable white balanced light emission (see, ¹Y. W. Ko et al, Thin Solid Films 426 (2003) 246-249).

These examples show just two of the mechanisms that are being explored for obtaining white light from OLED devices. However, as in all the other known OLED fabrication methods ultra-thin organic films must be formed and preserved. Importantly, most if not all the mechanisms that are being explored for producing thin film OLED white light sources are also adaptable to the inventive OLED particulate/matrix device architecture. This is the case because the inventive OLED particulate can be formed with the same layered structure as these planer ultra-thin film OLED devices.

In addition to the potential use of OLED devices for lighting purposes, there has been much effort recently in obtaining the advantages of the OLED phenomenon for video display devices. Consequently, much of the OLED device research is being conducted by display manufacturing companies. Currently, Kodak's small molecule vacuum-deposition method (see, www.kodak.com/US/en/corp/display/indexjhtm) holds the lead in commercialization of OLED manufacturing. While this is the case, it is limited to very small displays as would be found in cell phones and digital cameras. It now appears that the manufacturing advantages of the polymer-based OLED will soon make it the better choice for the manufacture of larger format devices, such as OLED panel lighting and displays.

Competition for OLED device manufacturing technology comes from smaller entities such as Cambridge Display Technologies, and Universal Display Corporation, with a host of larger company and university relationships in place, as well as the chemical manufacturers and others with special interests. Dow, Dupont, IBM, Sharp, Samsung, Kodak and many other large and small companies have varied interests in OLED technologies. Much of the OLED activity is focused on the development of raw materials and fabrication methods, with large companies such as Dow and Dupont working towards that end in consort with a host of smaller specialty companies.

The inkjet printer manufacturer Seiko-Epson is working with CDT to improve the raw materials and create inkjet-printing technology based equipment and methods that can be used in OLED device manufacturing. However, there remain serious disadvantages to adapting inkjet printing to OLED light panel fabrication.

### SUMMARY OF THE INVENTION

It is an object of the present invention to overcome the drawbacks of the conventional art. It is another object of the present invention to provide an improved device structure and method of manufacturing an organic and/or inorganic light active device. It is a further object of the present invention to provide a method for manufacturing composite particles. It is a still further object of the present invention to provide a method for manufacturing composite OLED particles.

In accordance with the present invention, a light active device is a component or system for generating light in response to electrical energy (energy-to-light), generating light in response to radiation energy (light-to-light), and generating energy in response to radiation energy (light-to-energy)

In accordance with the present invention, the usual ultra-thin OLED films are replaced by a thicker, much more robust particulate/matrix composite film. Applicant's recent experiments have shown that this composite structure is achievable for forming an OLED light panel device that is far superior in both functionality and manufacturability as compared with all other existing OLED device fabrication technologies.

A method of making a multi-layered light active particle. A substrate is provided. The substrate may be, for example, a piece of polished glass. A first light active layer is formed on the substrate. The first light active layer may be, for example, a hole transport organic film layer. A second light active layer is formed on top of the first light active layer. The second light active layer may be, for example, an electron transport organic film layer. The first light active layer and the second light active layer are then removed from the substrate to form multi-layered particles.

A release layer can be formed between the substrate and the first light active layer to facilitate the removal of the multi-layered particles. The release layer may comprise at least one of a sublimable material, a vaporizable material and a dissolvable material.

The first light active layer may comprise a n-semiconductor and the second light active layer comprises a p-semiconductor. Additional layers may be formed on top of the second light active layer. The first light active layer, the second light active layer and the additional layers may comprise materials including an n-semiconductor, a p-semiconductor, a hole transport material, an emitter, a re-emitter, a hole blocker, an electron transport material, a buffer, a relatively low work function material, a relatively high work function material.

An anode layer may be formed before forming the first light active layer and/or a cathode layer may be formed after forming the second light active layer. The first and the second light active layer may comprise, respectively, a hole transport, emitter, electron transport, hole blocker, guest/host system.

The layers may be patterned into individual volumes so that when removed from the substrate the individual volumes form individual particles comprised of a multi-layered light active particles. The pattern may be to form a consistently sized particle, such as by etching through a photo-resist grid, or it may be to form a randomly sized particle, such as by pulverizing. The particles can be filtered, or otherwise sorted, to obtain a desired uniformity of size. The patterning includes the step including at least one of forming a photo-resist layer, etching, solvent washing, laser ablatement, pulverizing, and scraping, other patterning methods may also be employed. In the case of pulverizing, cryogenic pulverizing can be used, such as using a whirly bug, grinding, or other pulverizing method.

In accordance with another aspect of the invention, a method is provided for making polymer blend light active particles. The inventive method includes the steps of, providing an solution comprised of a first organic light active diode material and a second organic light active diode material in a solvent. A non-solvent is provided and the solution is added to the non-solvent to cause a precipitation reaction. The precipitation reaction results in multi-layered particles comprising the first and second organic light active diode material layers. The first and second organic light active diode materials can be added to the non-solvent in a single stream in a common solvent, or two separate streams. The thus formed particles can then be further reduced in size using known techniques for forming small sized (up to nano) particles, including using a microfluidizer machine.

In accordance with another aspect of the present invention, a method is provided for making a light active electronic device. The inventive method includes the steps of: providing at least one of organic and inorganic light active particles in an particle non-solvent liquid; adding a charge transport carrier polymer to the particle non-solvent liquid to form a fluid carrier/particle mixture; and disposing the mixture between electrodes to form a light active electronic device. The inventive method may further comprise the step of aligning the particles in the mixture; and then hardening the fluid carrier to lock in the alignment of the particles.

The charge transport material may comprise, for example, at least one of an ionic transport material, a conjugated polymer charge transport material and a semi-conductor charge transport material. The particles may comprise a multi-layered organic particle comprising hole transport and electron transport layers. The particles may comprise an inorganic p/n junction particle, such as an inorganic LED chip. The fluid carrier can be hardened to form a solid-state light active electronic device. The fluid carrier may also be selectively hardened to improve device properties, such as flexibility.

### BRIEF DESCRIPTION OF THE DRAWINGS

FIG. 1 illustrates the inventive composite film consisting of OLED particles aligned within a solid-state carrier matrix;

FIG. 2 shows a mixture of randomly dispersed OLED particulate in a fluid conductive carrier matrix is disposed between a top and a bottom electrode;

FIG. 3 shows an aligning field fixing the position of the particulate chains while the fluid matrix is cured or cooled;

FIG. 4 shows a completed light panel, display device or photovoltaic device consisting of point sources of light emission (aligned particulate) in a solid-state protective matrix (hardened carrier);

FIG. 5 illustrates the inventive manufacturing processes for the production of large and small scale roll-to-roll OLED devices;

FIG. 6(a) illustrates that ITO or metal particles adhered to a release layer can be patterned using photoresist/selective etching process. Spin coating, VD and other layer forming methods can be used to form the layers;

FIG. 6(b) shows that the unpatterned layers can be formed by solution processing, vacum deposition, silk screen or other methods. A final layer of photo resist is formed on top;

FIG. 6(c) shows that the photoresist may be patterned through a grid mask, and selectively etched;

FIG. 6(d) shows the step of selective etching and solvent wash (using appropriate etching and solvent system) to limit undercutting;

FIG. 6(e) shows the liberated OLED particulate released from the release layer and photoresist (which may be dissolved away, sublimed, or otherwise removed, if necessary);

FIG. 7(a) shows an alternative OLED particle;

FIG. 7(b) shows another alternative OLED particle;

FIG. 7(c) shows another alternative OLED particle;

FIG. 7(d) shows another view of alternative OLED particle shown in FIG. 7(d);

FIG. 7(e) shows another alternative OLED particle;

FIG. 8(a) shows the formation of OLED multilayered device including a cracking layer and a glass substrate in accordance with another inventive method of manufacturing OLED particulate;

FIG. 8(b) shows the OLED multilayered device removed from the glass substrate;

FIG. 8(c) shows the OLED multilayered device and cracking layer cracked into OLED particulate;

FIG. 8(d) shows the OLED multilayered particulate formed in accordance with this aspect of the present invention

FIG. 9(a) is a photograph showing an emissive particulate/conductive carrier concept experimentally demonstrated and proven viable using very small inorganic LEDs suspended in an ionic conducting fluid composed of a fluid poly(ethylene glycol) (PEG) polymer doped with a conductive salt;

FIG. 9(b) is a schematic diagram of the prototype shown in FIG. 9(a);

FIGS. 9(c) is a photograph showing the results of an experiment in which a chromophore, electron transfer and hole transfer materials were ground together and coated from solvent on small aluminum filings and suspended in benzene between aluminum and ITO electrodes;

FIG. 9(d) is a photograph showing the prototype jig used in the experiment shown in FIG. 9(a);

FIG. 10 schematically shows a solid-state inorganic light active electronic device prototype demonstrating a light emissive particulate encased in a solid-state charge transport material;

FIG. 11 shows the experimental apparatus used to create polymer blend organic light active diode particles;

FIG. 12 is a flow chart showing the basic steps of an inventive method for forming organic light active particles;

FIG. 13 is a flow chart showing the basic steps of an inventive method for forming a light active electronic device;

FIG. 14 illustrates an organic light active particle formed from a polymer blend;

FIG. 15 illustrates the polymer blend organic light active particulate dispersed within a conductive carrier;

FIG. 16 illustrates the polymer blend organic light active particle showing light active sites;

FIG. 17 illustrates a multi-layered OLED nanoparticle in an electrical field in accordance with the present invention;

FIG. 18 illustrates a multi-layered OLED nanoparticle having injected charges migrating toward HT/ET interfaces within the particle; and

FIG. 19 illustrates a cascading electron efficiency mechanism occurring in a light active electronic device constructed in accordance with the present invention.

### DETAILED DESCRIPTION OF THE INVENTION

The present invention pertains to an OLED particulate/matrix matrix approach that is a wide departure from the conventional thin film methods. All the conventional OLED fabrication methods require forming what are nearly two-dimensional devices. That is, they are comprised of active layers of organic films with relatively large planer surface areas and hardly any thickness. The inventive approach uses the same cross sectional structure of the active layers that are necessary for efficient OLED emissions. However, instead of the large planar surfaces, which have proven so problematic to form and preserve, in accordance with the present invention, nanoparticle discrete point source emitters protected within a solid-state barrier matrix.

The device structure resulting from the inventive approach has superior long-term shelf and service life, stability and reliability of the electroluminescent system. Others have shown that the use of thicker films provides a passivation and smoothing layer to plastic substrates (see, T. Shimizu, A. Nakamura, H. Komaki, T. Minato, H. Spreitzer, and J. Kroeber, “Fabrication Technique of PELD by Printing Methods,” SID Digest'03, Vol. XXXIV(2), 1290-3 (2003). The use of cross-linked materials as the inventive carrier matrix reduces the permeation by water and oxygen that affects both the chromophore material and the active metal electrodes. At later stages of the present invention development the use of OLEDry (see, A. Yoshida, et al., 3-inch Full-color OLED Display using a Plastic Substrate,” Invited paper in SID Digest'03, Vol. XXXIV(2), 856-9 (2003).) or an additional moisture barrier such as SiON (see, Y. Tsuruoka, S. Hieda, S. Tanaka and H. Takahashi, “Transparent Film Desiccant for OLEDs,” SID Digest'03, Vol. XXXIV(2), 860-3 (2003).) could be considered.

The choice of flexible substrate depends partly on the relative cost of additional coating steps for PET versus fundamental polymer costs for PEN. The thicker layers employed also obviates the need to use a planarizing coating (see, J. G. Innocenzo, R. A. Wessel, M. O'Regan and M. Sellars, “Plastic Displays—Films for OLED Light panels,” SID Digest'03, Vol. XXXIV(2), 1329-31 (2003)) to handle normal substrate roughness or included particles. One of the inventive proposed fabrication systems, as described herein, uses slot-die coating. The use of die coating for a 100 nm PEDOT layer has been demonstrated (see, J. G. Innocenzo, R. A. Wessel, M. O'Regan and M. Sellars, “Plastic Displays—Films for OLED Light panels,” SID Digest'03, Vol. XXXIV(2), 1329-31 (2003)) along with the adhesion of pre-developed layers laminated together.

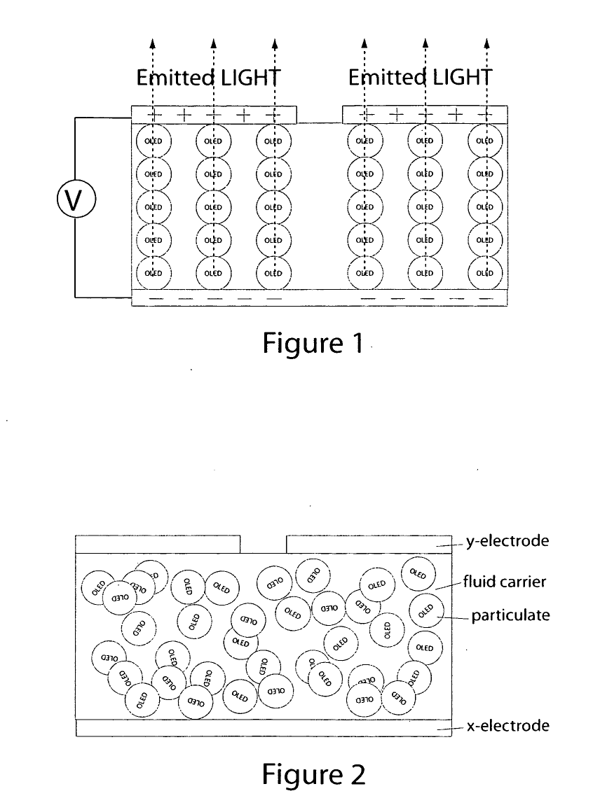

As shown in FIG. 1 inventive composite film consists of OLED particles aligned within a solid-state carrier matrix. The particles have the same basic structure and functionality of the conventional OLED thin film devices, but avoid all the thin film processing issues. The resulting device structure holds the promise of overcoming the persistent final hurdles to OLED commercial viability.

As shown in FIG. 2, during the fabrication of an OLED light panel, a mixture of randomly dispersed OLED particulate in a fluid conductive carrier matrix is disposed between a top and a bottom electrode. The electrodes are pre-formed on top and bottom substrates. In a process similar to electrorheological fluid devices, an aligning field applied between the top and bottom electrodes initiates a migration and controlled orientation of OLED particulate. The result is the formation of electrically conductive/emissive particulate chains between electrodes within the fluid carrier.

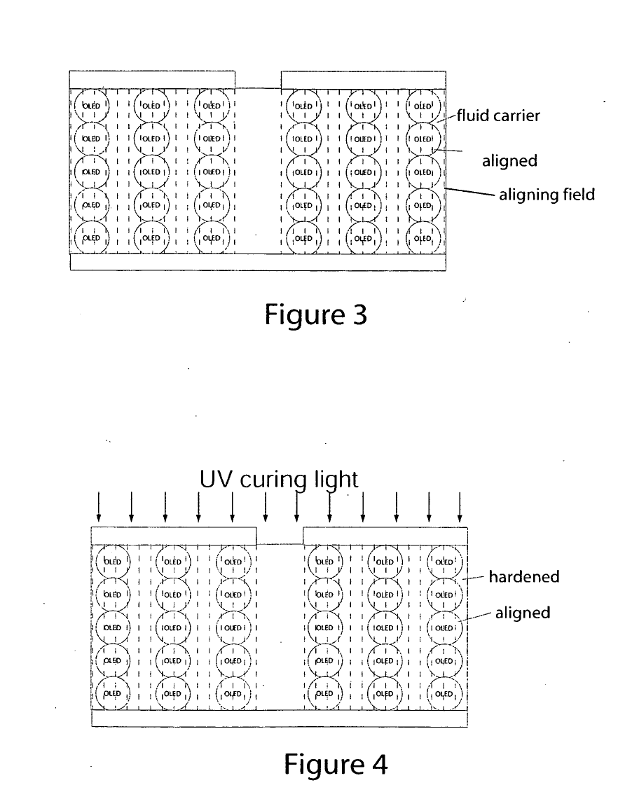

As shown in FIG. 3, the aligning field fixes the position of the particulate chains while the reactive fluid carrier is cured or cooled. The carrier matrix transforms from a fluid to a cured/hardened solid-state matrix upon the application of ultraviolet light, or heat; alternatively molten polymer carriers would fix the alignment of the carrier particulate upon cooling and solidification. The OLED particles are environmentally protected against air and moisture attack by the barrier created by the hardened carrier. Commercially available flexible substrates (plastic films) may be utilized to complete the encapsulation. Because OLED devices based upon the inventive particulate technology result in devices with much greater electrode spacing compared to conventional OLEDs formed from thin-films, many of the problems associated with current state-of-the art OLED fabrication methods are avoided, and the resulting light panel structures should prove to be highly flexible and robust.

As shown in FIG. 4 the completed light panel consists of point sources of light emission (aligned particulate) in a solid-state protective matrix (hardened carrier). When voltage is applied to the electrodes, each of the OLED particles emits light. The appropriate mixture of color emitters will enable a tunable white light, or any other color to be produced. The resulting device structure is a potent barrier to water and oxygen. The much wider gap between the electrodes greatly reduces the problem of dust and particle contamination. If a short between the electrodes does occur, the structure is self-healing by automatically disconnecting the short. The inventive fabrication process is readily adaptable to roll-to-roll processing on flexible plastic substrates using a variation of well-established polymer film fabrication methods

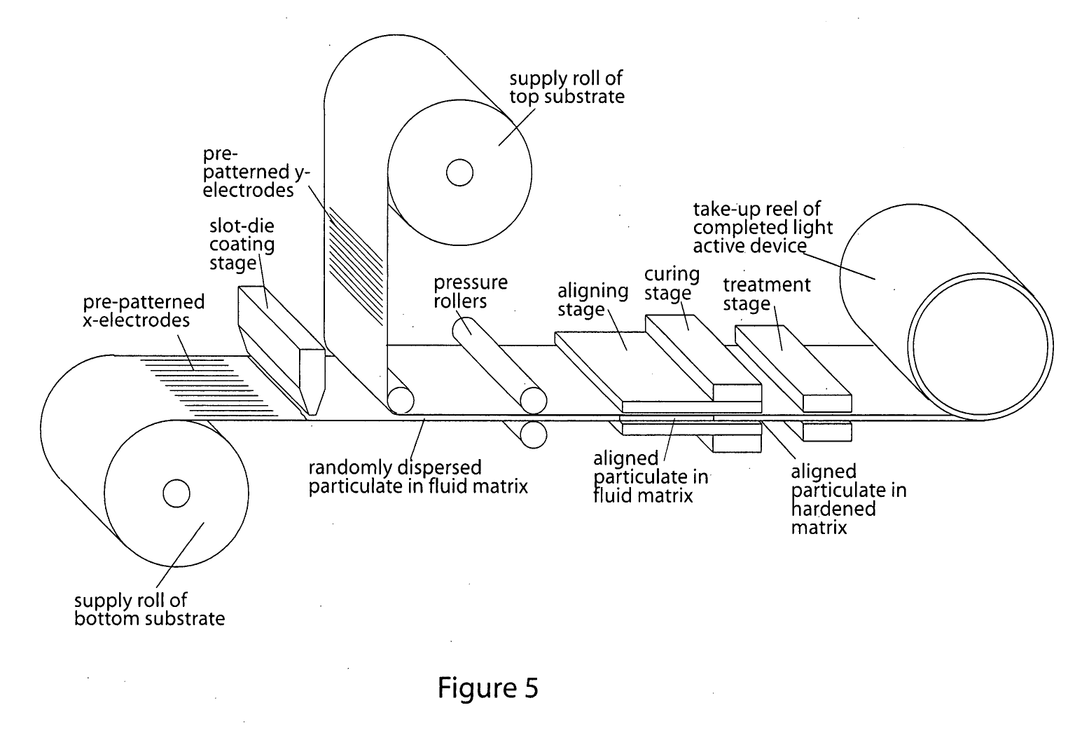

As shown in FIG. 5, in conjunction with the development of unique, nanoparticulate-based OLED compositions, we are also developing novel manufacturing processes for the production of large scale roll-to-roll OLED devices. One process we are exploring is derived from conventional polymer film fabrication and coating techniques and can be adapted towards the formation of solid state, flexible, high-quality light panels.

This fabrication process begins with a supply roll of bottom substrate and a supply roll of top substrate. The substrates have preformed on them top and bottom electrodes. A slot-die coating stage introduces onto the bottom substrate a film of a fluid carrier containing randomly dispersed OLED particulate. The top substrate is placed over this film. Pressure rollers ensure the proper uniform thickness of the particulate/matrix mixture between the substrates. At an aligning stage, an aligning field is applied to the OLED particulate. This applied field causes the particulate to orient and align within the still fluid carrier. With the applied field maintaining the position of the aligned particulate, the carrier is hardened at the curing stage. The aligned particulate is locked in position between the top and bottom electrode grids within the now solid-state carrier. A treatment stage can be provided, as necessary, to perform a heat or pressure treatment, or other process, on the completed light panel before it is rolled up onto the take-up reel. The continuous roll can then be cut and trimmed to a desired light panel size and shape.

Using the inventive OLED material composition and fabrication method, the problems of OLED light panel encapsulation are overcome by the combination of the barrier properties of the inventive cured carrier and the judicious selection of polymer film substrates. Because of the particle/carrier composite nature of the inventive OLED material, the inclusion of desiccant and/or scavenger protective particles within the OLED particulate composition can further enhance the protection of the OLED materials.

Fragile organic thin films are replaced by robust OLED particulate or microcapsules that are protected within a solid-state matrix. High quality white light can be obtained through the appropriate selection of color emitter particulate within a single layer, or multiple stacked layers of white light constituent emitters can be used. The inventive fabrication method will be extremely fast, material efficient, and will make the manufacture of very large, thin, bright, flexible, lightweight, light panels a near-term practical reality.

Examples of OLED Particles

The OLED particulate can be formed by a number of techniques. Some techniques are well-known and have been applied towards the formation of nanoparticles for drug delivery. Among the inventive proprietary technology is a method for forming an organic light active particle composed of individual layered components that provide the required hole transport and polymer emitting functions, etc. In essence, each particulate is a complete OLED emitting body, with the exact same layer structure as the already-proven thin film OLED devices. This particle structure enables, for example, the appropriate layered structure for forming a phosphorescent OLED particulate enabling energy efficient triplet emissions. This composition has the potential to achieve very high efficiencies in the conversion of electrical-to-light energy.

Example of a Potential Carrier Matrix

The inventive unique OLED device structure includes minute point source emitters self-assembled within a hardened carrier matrix. The ideal carrier matrix is a charge transporting organic material that is fluid during the coating and particle aligning stages and becomes hardened after the aligning stage so that the entire OLED light panel is a continuous solid-state device. As an example of a candidate carrier matrix material, an intrinsically conductive polymer, Poly(thieno[3,4-b]thiophene), has been shown to exhibit the necessary electronic, optical and mechanical properties(see, ¹Poly(thieno[3,4-b]thiophene): A p- and n-Dopable Polythiophene Exhibiting High Optical Transparency in the Semiconducting State, Gregory A. Sotzing and Kyunghoon Lee, 7281 Macromolecules 2002, 35, 7281-7286). As prepolymer it is a fluid, but electropolymerizes to produce a patterned, conductive, transparent polymer. We have also identified other candidate carrier matrices that will be tried, including PEDOT:PSS and BCP.

The inventive unique device structure includes the combination of particles in a protective solid-state cured carrier encased in flexible, barrier substrates and should not require further encapsulation. There are three modes of moisture and oxygen barrier protection of the resulting structure: 1) the external substrate film materials with barrier treatments if necessary; 2) the barrier properties of the cross-linked carrier itself; and 3) the nature of the structure produced. Table I discusses the barrier properties of the materials using conventional units from transfer rate studies (wvtr=gm/100 in²·24 hrs; otr=cc·mil/100 in²/day·atm):

TABLE I
Barrier Properties

| | Water Vapor | Oxygen |
|---|---|---|
| Material | Transfer Rate | Transfer Rate |
| PET | 4.31 | 11.11 |
| PEN | 2.12 | 2.76 |
| 75% PET/25% PEN | 2.73 | 5.32 |
| Cross-linked carrier | 0.17 | 0.24 |
| COC (i.e., Topas) | 0.03 | 5.40 est. |
| Corning Flexible Glass | 0 | 0 |

The flexible barrier substrates can be either PET or PEN or a transesterified blend of PET/PEN consisting of at least 25% PEN that has been melt processed into sheet to make at least a 10% transesterification causing the blend to be miscible and transparent. Subsequent treatment with a Barix™-type coating, or with silicon oxy-nitride (SiON), or with an internal layer of Oxydry® depends upon the requirements of the materials between the layers. Corning also offers a flexible glass that could be a viable substrate candidate.

The cross-linked carrier has much better barrier properties than thermoplastic materials. Dispensing the OLED particles in these carriers will reduce the susceptibility to moisture and oxygen attack, especially when compared against thin-film OLEDs produced by conventional techniques. If the particles were to be aligned in a thermoplastic melt, high barrier plastics such as cyclic polyolefins (COCs) known for their barrier properties would be employed. Finally, because the thickness of the inventive structure is at least 200 times thicker than conventional thin-film OLED structures, and consists of myriad individual light emitting bodies, the oxygen and moisture has further to penetrate before doing damage and any damage could be self correcting by the inclusion of scavenging agents within the particles themselves. Scavenging materials may be added for oxygen and moisture protection of the low work metal electrodes (See, L. M. Higgins, “Hermetic and Optoelectronic Packaging Concepts Using Multilayer and Active Polymer Systems,” Vol. 30(4), Advancing Microelectronics, July/August 2003, pp. 6-13).

In accordance with an embodiement of the inventive OLED particulate, the particulate are very small OLED devices in themselves with active metal, chromophore and hole transfer layers. By developing these particles in smaller and smaller formats, better device performance should be obtained.

One method for forming the OLED particulate is described herein. In this method, conventional OLED device fabrication techniques are employed to form a multiple organic layer structure on a transparent anode layer. This structure is then separated into particles using etching, cutting or laser ablatement, we have established relationships with companies who can perform the ion etching and laser ablatement process. The inventive facilities already include most of the equipment and materials necessary to perform this OLED particle formation.

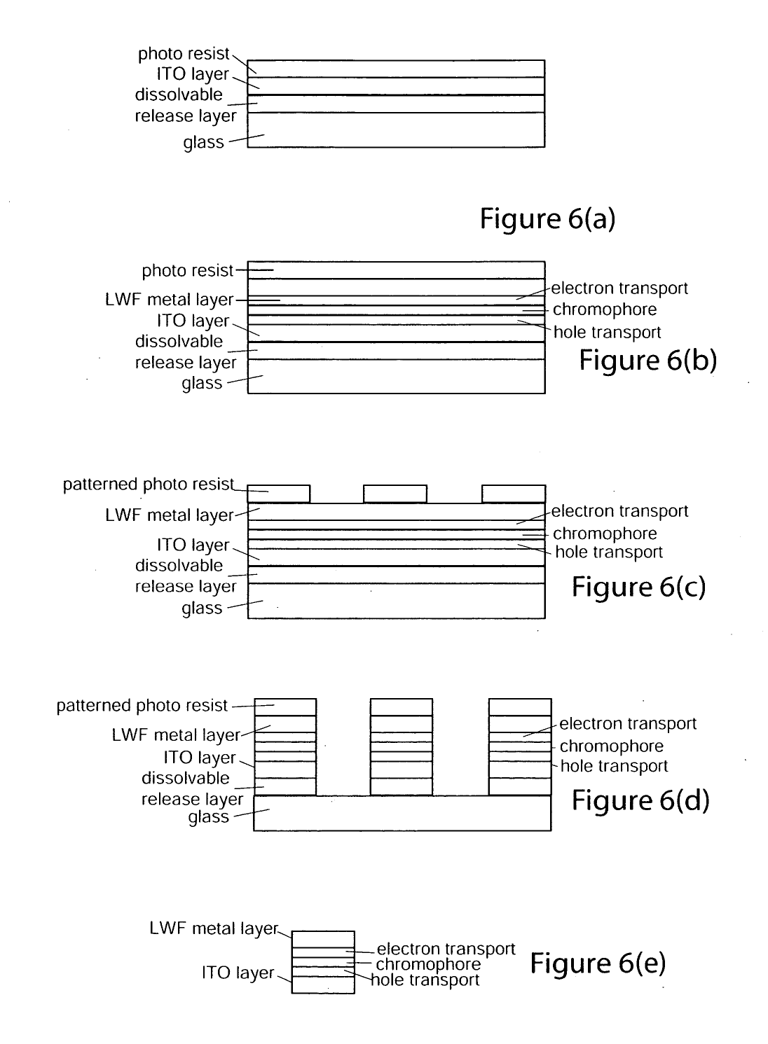

These drawings are schematic representations and do not represent actual layer and substrate size. FIG. 6(a) illustrates that ITO or metal particles adhered to a release layer can be patterned using photoresist/selective etching process. Spin coating, VD and other layer forming methods can be used to form the layers. FIG. 6(b) shows that the unpatterned layers can be formed by solution processing, vacum deposition, silk screen or other methods. A final layer of photo resist is formed on top. FIG. 6(c) shows that the photoresist may be patterned through a grid mask, and selectively etched. FIG. 6(d) shows the step of selective etching and solvent wash (using appropriate etching and solvent system) to limit undercutting. FIG. 6(e) shows the liberated OLED particulate released from the release layer and photoresist (which may be dissolved away, sublimed, or otherwise removed, if necessary).

As shown, a release layer is formed on a glass substrate (Step One). The release layer may be, for example, a soluble photoresist, or other material that can be formed as a thin layer and dissolved away using a solvent that does not attack the OLED device materials.

On top of the release layer, a conductive transparent electrode is formed by spin coating, sputtering, or other suitable film formation technique. The conductive transparent electrode may be, for example, ITO, PEDOT:PSS (Available as Baytron P from Bayer), or Poly(thieno[3,4-b]thiophene) (see, Poly(thieno[3,4-b]thiophene): A p- and n-Dopable Polythiophene Exhibiting High Optical Transparency in the Semiconducting State, Gregor A. Sotzing and Kyunghoon Lee, 7281 Macromolecules 2002, 35, 7281-7286) (Step Two).

On top of the conductive transparent electrode, a hole transport layer is formed by spin coating, vacuum deposition, or other suitable film formation technique. The hole transport layer may be, for example, PEDOT:PSS, N,N′-Bis(naphthalen-1-yl)-N,N′-bis(phenyl)benzidine (Available from HW Sands, cat. no. OSC7534) (Step Three).

On top of the conductive transparent electrode, a chromophore emitter layer is formed by spin coating, vacuum deposition, or other suitable film formation technique. The chromophore emitter layer may be, for example, Poly[2-Methoxy-5-(2′-ethylhexyloxy)-1,4-phenylenevinylene] (Available from HW Sands, cat. no. OHA9576) (Step Fthe inventive).

On top of the chromophore emitter layer, an electron transport layer is formed by spin coating, vacuum deposition, or other suitable film formation technique. The electron transport layer may be, for example, 2,9-Dimethyl-4,7-diphenyl-1,10-phenanthroline (Available from HW Sands, cat. no. OPA3972) (Step Five).

On top of the electron transport layer, a low work function cathode electrode layer is formed by spin coating, sputtering, or other suitable film formation technique. The cathode layer may be, for example, Aluminum, Calcium, etc. Further, additional layers, such as Cesium Fluoride (see, Electronic line-up in light-emitting diodes with alkali-halide/metal cathodes, J. Appl. Phys., Vol. 93, No. 10, 15 May 2003), may be formed prior to the cathode layer to enhance the OLED performance. (Step Six).

Once the cathode layer has been formed, the multilayered device structure is patterned into individual OLED particles. This patterning can be performed by a number of known techniques, such as ion etching, laser ablatement or other suitable process (Step Seven). Alternatively, a layer of photoresist can be formed on top of the cathode layer and patterned through a light mask and rinsing. The OLED particulate is then patterned through selective solvent etching.

The release layer (and photoresist, if present) is dissolved to liberate OLED particulate from the glass substrate. The particle is a schematic representation. The OLED particle structure obtained using this method will include the top (LWF metal) and bottom (ITO) electrodes and essentially be micro-miniature replicas of full size OLED devices. By forming a control full size device at the same time and under the same conditions as the particles, we will be able to get an exact measurement from the full size device of the expected electrical and optical properties of the particles.

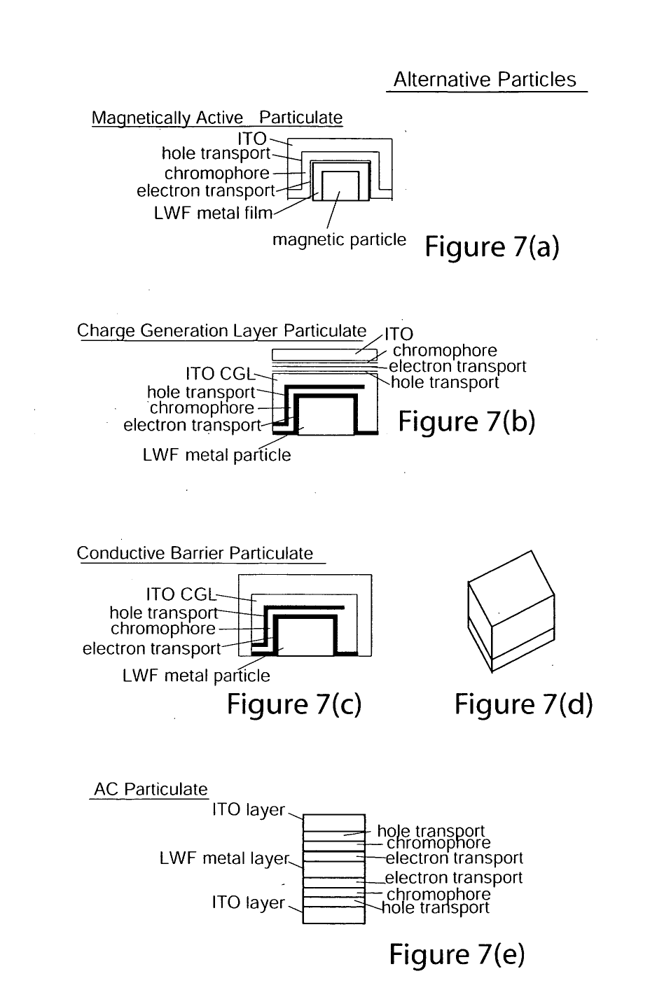

FIG. 7(a) shows an alternative OLED particle. Magnetic particle component enables alignment of OLED particulate along magnetic field lines. Electrostatically attractive particle component can also be used to improve the electrostatic alignment process.

FIG. 7(b) shows another alternative OLED particle. The middle ITO layer functions as Charge Generation Layer (CGL), this structure has been shown to improve current efficiency.

FIGS. 7(c) and (d) show another alternative OLED particle. Deposited overcoating of a transparent (or color filter) coating protects the inner layers and creates a more completely encapsulated structure. Lead can be formed to the ITO and device made into surface mount LED size (or smaller or larger).

FIG. 7(e) shows another alternative OLED particle. The particle can be AC or DC driven (charges can enter central metal cathode through the sides).

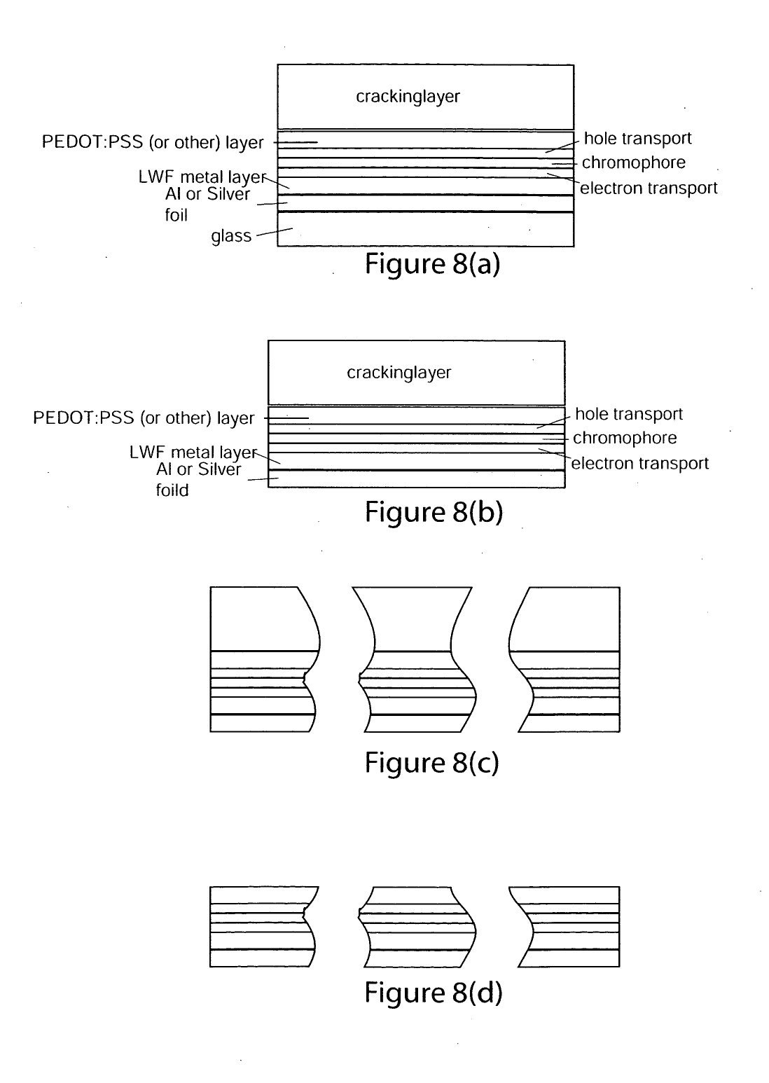

FIG. 8(a) shows the formation of OLED multilayered device including a cracking layer and a glass substrate in accordance with another inventive method of manufacturing OLED particulate. This system can be employed in a continuous roll process, where a “treadmill” type system where the tread is a release substrate on which is formed the layers. Once the multi-layered structure is formed, multi-layered flakes can be harvested from the tread. This system can be employed in a continuous vacuum deposition process where bulk quantity of flakes can be made without breaking vacuum. FIG. 8(b) shows the OLED multilayered device removed from the glass substrate. Layers are formed from Al or Silver foil on up. Final layer is a cracking layer that forms desired particulate with the desired properties. For example, the cracking layer can be something that sublimes at temp less than the melting of all the OLED device layers, so when it sublimes, nothing else is effected. Small particles are formed when pulverized for example, in liquid nitrogen (or some condition that would make all the layers also crack apart (other layers compositions are possible, for example, the metal foil may be replaced with metal powder or a polymer).

FIG. 8(c) shows the OLED multilayered device and cracking layer cracked into OLED particulate. FIG. 8(d) shows the OLED multilayered particulate formed in accordance with this aspect of the present invention. The layers are removed from the glass (or other substrate, including a Teflon coated web, etc.), put in liquid N2, then in a vessel for grinding a solid into a powder, and pulverized. When the cracking layer is sublimed, the other layers are left as complete OLED particulate. The thickness is the stacked layer, the larger area (top and bottom) are dependent on the cracking layer particle size.

The OLED particles are then disposed in a carrier matrix, such as poly(thieno[3,4-b]thiophene). This mixture will then be disposed between an ITO electrode and a metal electrode and voltage applied causing light emission from the OLED particles.

Experiments:

To date, we have made significant progress towards demonstrating the viability of the inventive unique OLED nanoparticulate/matrix device structure. The inventive efforts have yielded very significant results as illustrated below:

Inorganic LED Emissive Particle Demonstration

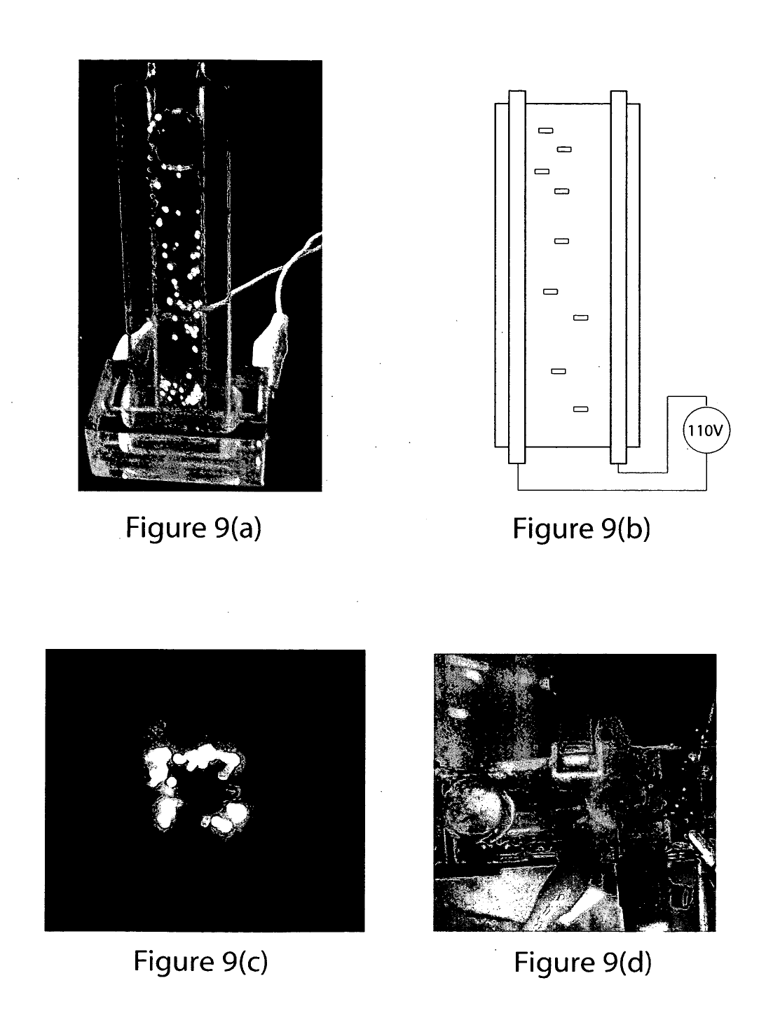

As shown in FIGS. 9(a) and 9(b), an emissive particulate/conductive carrier concept was demonstrated and proven viable using very small “particulated” inorganic LEDs suspended in an ionic conducting fluid composed of a fluid poly(ethylene glycol) (PEG) polymer doped with a salt. When connected to 110 v AC, these 3 v DC devices light up without burning out.

Organic LED Emissive Particle Demonstration

Applicant also conducted experiments with dry ground OLED particulate. Even in experiments where oxygen and moisture were not rigorously controlled, the results are very highly promising. As shown in FIGS. 9(c) and 9(d), chromophore, electron transfer and hole transfer materials were ground together and coated from solvent on small aluminum filings and suspended in benzene between aluminum and ITO electrodes. With film thickness of about 0.5 mm and applied voltage of 20 V, a bright orange OLED particulate emission was observed.

Solid-State Charge Carrier

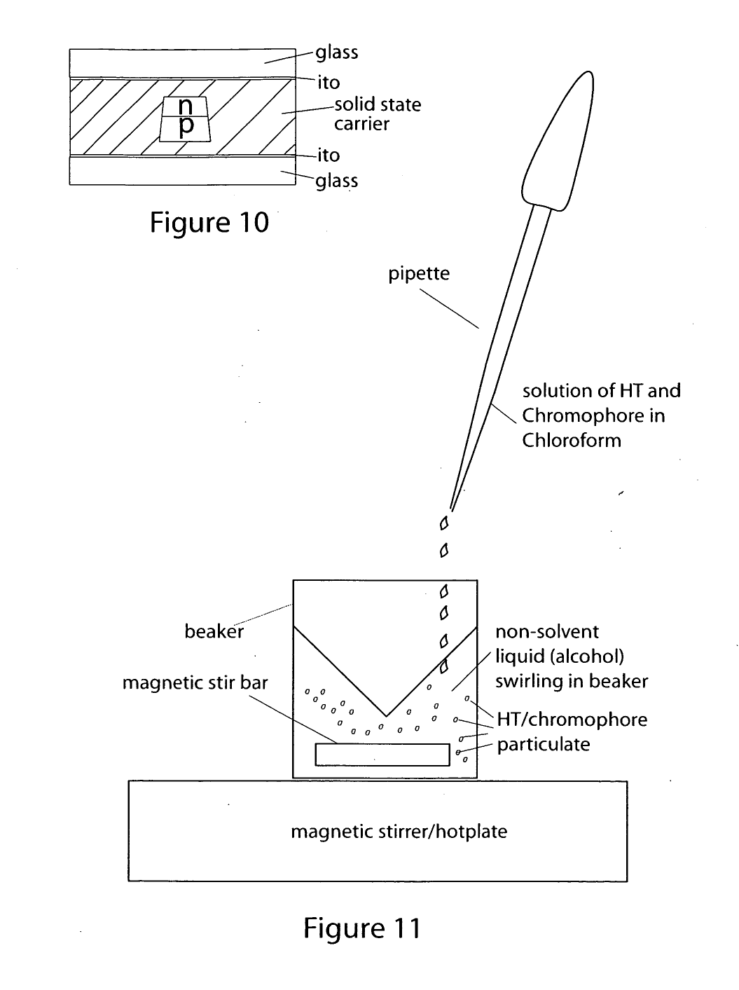

FIG. 10 schematically shows a solid-state inorganic light active electronic device prototype demonstrating a light emissive particulate encased in a solid-state charge transport material. Applicants demonstrated the effectiveness of an emissive p/n junction diode particulate encased in a solid-state polymer charge carrier. The bright light observed when a driving voltage is applied to the device clearly demonstrates the core innovative concept that enables the inventive light active electronic device in the various configurations described herein.

Polymer blend OLED particles

FIG. 11 shows the experimental apparatus used to create polymer blend organic light active diode particles. Applicant has made HT/chromophore (i.e., ET) particles using a method wherein a magnetic stir bar is used to create a swirling non-solvent liquid (e.g., alcohol). A solution of HT and chromophore is slowly droppered into the swirling non-solvent. Upon coming in contact with the alcohol, the HT and chromophore precipitate out of the choloroform, forming HT/chromophore particulate. This particulate can be reduced down to 100 nm or less using a microfluidizer machine available from Microfluidics, Newton, Mass. The ratio, composition, solvents and other parameters can be varied to create particles having desirable properties. As just one example, a hole blocker, hole transport and chromophore combination of polymers can be provided in the solution that is droppered into the non-solvent.

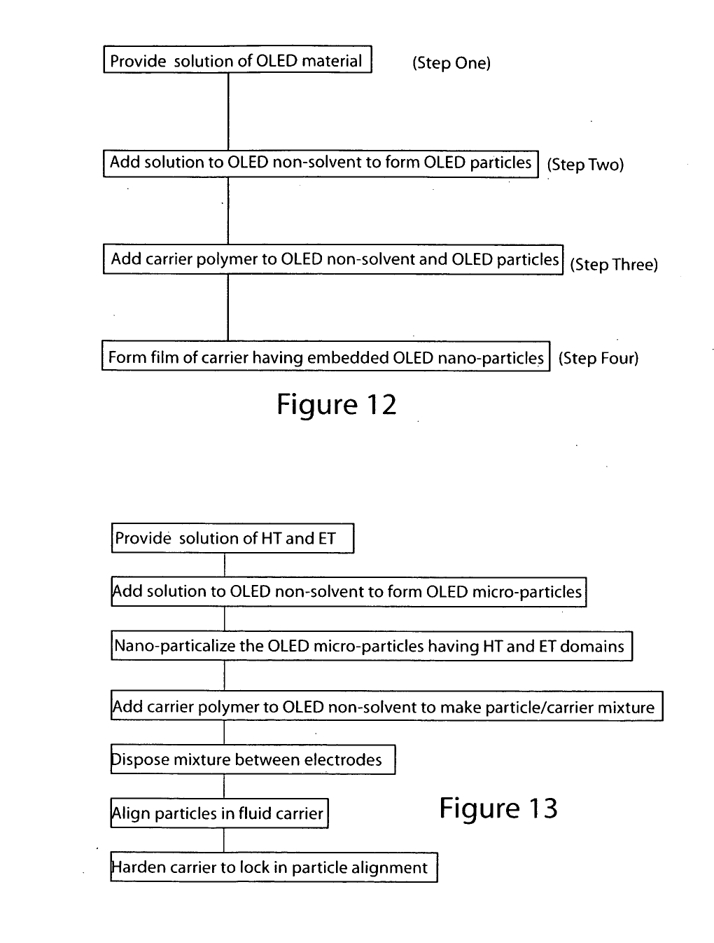

FIG. 12 is a flow chart illustrating the basic steps to making an OLED nanoparticle in accordance with one aspect of the present invention. In accordance with the inventive method, a solution of OLED material is provided. In accordance with another aspect of the invention, a method is provided for making polymer blend light active particles. The inventive method includes the steps of, providing an solution comprised of a first organic light active diode material and a second organic light active diode material in a solvent. A non-solvent is provided and the solution is added to the non-solvent to cause a precipitation reaction. The precipitation reaction results in multi-layered particles comprising the first and second organic light active diode material layers. The first and second organic light active diode materials can be added to the non-solvent in a single stream in a common solvent, or two separate streams. The thus formed particles can then be further reduced in size using known techniques for forming small sized (up to nano) particles, including using a microfluidizer machine.

FIG. 13 is a flow chart showing the basic steps of an inventive method for forming a light active electronic device. In accordance with another aspect of the present invention, a method is provided for making a light active electronic device. The inventive method includes the steps of: providing at least one of organic and inorganic light active particles in an particle non-solvent liquid; adding a charge transport carrier polymer to the particle non-solvent liquid to form a fluid carrier/particle mixture; and disposing the mixture between electrodes to form a light active electronic device. The inventive method may further comprise the step of aligning the particles in the mixture; and then hardening the fluid carrier to lock in the alignment of the particles.

The charge transport material may comprise, for example, at least one of an ionic transport material, a conjugated polymer charge transport material and a semi-conductor charge transport material. The particles may comprise a multi-layered organic particle comprising hole transport and electron transport layers. The particles may comprise an inorganic p/n junction particle, such as an inorganic LED chip. The fluid carrier can be hardened to form a solid-state light active electronic device. The fluid carrier may also be selectively hardened to improve device properties, such as flexibility.

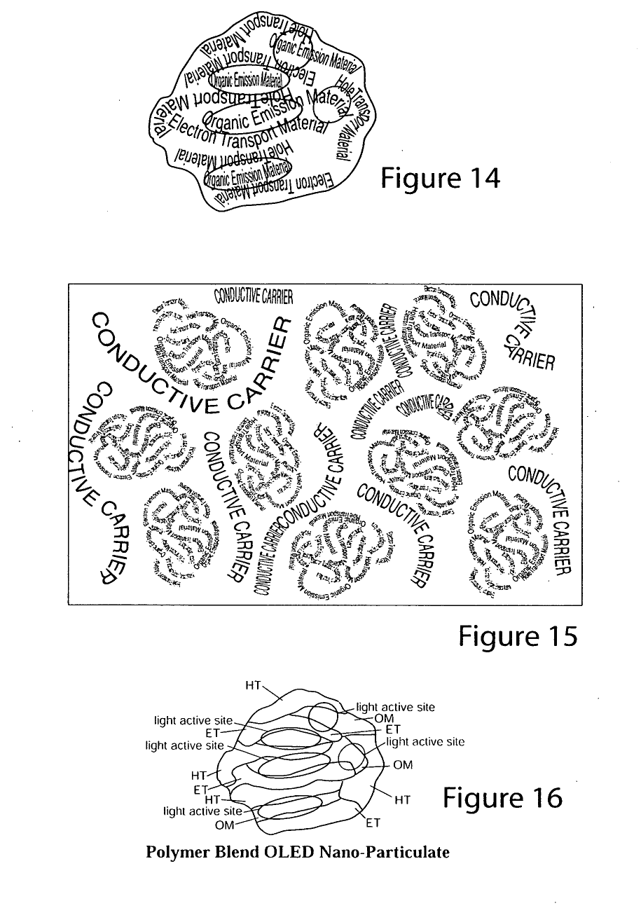

As also described in applicant's copending U.S. patent application Ser. No. 10/375,728, which is incorporated by reference herein, FIG. 14 illustrates an organic light active particle formed from a polymer blend and FIG. 15 illustrates the polymer blend organic light active particulate dispersed within a conductive carrier. The organic light active particulate may include particles comprised from a polymer blend, including at least one organic emitter blended with at least one of a hole transport material, an electron transport material and a blocking material. The polymer blend may be comprised of emitters that respond to different turn-on voltages to effect a multicolor device. The polymer blend particulate can be dispersed within a carrier that includes at least one of the hole transport, electron transport, hole blocker, or other OLED constituent. The carrier may also include other performance enhancing materials, such as lithium, calcium, low work metals, charge injection facilitators, light-to-light emitters (similar to the coating on a florescent light tube) to obtain the desired light emission. As described elsewhere herein, other particulate and carrier additives can be incorporated to enhance the characteristics of the OLED device. FIG. 16 illustrates the polymer blend organic light active particle showing light active sites. Upon the application of electrical field to the electrodes, sites within the polymer blend particle will act as point sources of light emissions. These light active sights are located where the appropriate constituents of the polymer blend meet so that electrons and holes injected into the semiconductor material combine into excitons and decay with the release of photons.

The organic light active particulate may include microcapsules having a polymer shell encapsulating an internal phase. The internal phase and/or the shell can be comprised of the polymer blend including an organic emitter blended with at least one of a hole transport material, an electron transport material and a blocking material. As with the other constructions of the inventive OLAM devices and material compositions, depending on the material compositions and the device structure, this polymer blend can be used to emit radiation of different wavelengths and can also be used for light-to-light and light-to-energy devices, such as solar cell and photodetectors. These structures and compositions can also be used for bio-sensors and other organic light active applications.

One way to make the polymer blend particulate is to precipitate out the particles from a solution comprised of the OLED constituents in a common solvent. Applicant has experimentally formed a polymer blend particulate from the constituents Poly[2-Methoxy-5-(2′-ethylhexyloxy)-1,4-phenylenevinylene]; N,N-Di-(napthalen-a-yl)-N,N-diphenyl-benzidine; and 2,9-Dimethyl-4,7-diphenyl-1,1-phenanthroline. These OLED materials were obtained from H.W., Sands Corp, Jupiter, Fla. The three OLED constituents were first dissolved in a common solvent, chloroform, and then a non-solvent was added to form a precipitant of the blended polymers.

Nanoparticles are used in applications, such as drug deliver devices. Others have shown that very small polymer-based particles can be made by a variety of methods. These nanoparticles vary in size, typically from 10 to 1000 nm. A drug can be dissolved, entrapped, encapsulated or attached to a nanoparticle matrix. Depending on the method of preparation, nanoparticles, nanospheres or nanocapsules can be obtained. (see, Biodegradable Polymeric Nanoparticles as Drug Delivery Devices, K. S., Soppimath et al., Journal of Controlled Release, 70(2001) 1-20, incorporated by reference herein). In accordance with the present invention, an OLED particulate can be formed having a very small particle size. The small particle size offers a number of advantages. For example, the ultimate resolution available of a display may be dependent on the size limitation of the OLED particles. Thus OLED nanoparticles utilized in accordance with the inventive fabrication methods will enable extremely high resolution display devices. Also, the very small OLED particle size will enable more light point sources within a given volume, such as the volume making up a display pixel. A large number of light point sources can result in more uniform pixel characteristics, longer device lifetimes and more efficient power consumption. In accordance with the present invention, various methods can be employed to form the OLED nanoparticles. The various methods disclosed in this reference for the formation of drug delivery nanoparticles can be adapted for the formation of OLED nanoparticles. These methods include the solvent evaporation method, spontaneous emulsification, solvent diffusion method, salting out/emulsification-diffusion method, production of OLED nanoparticles using supercritical fluid technology, the polymerization of monomers, and nanoparticles prepared from hydrophilic polymers.

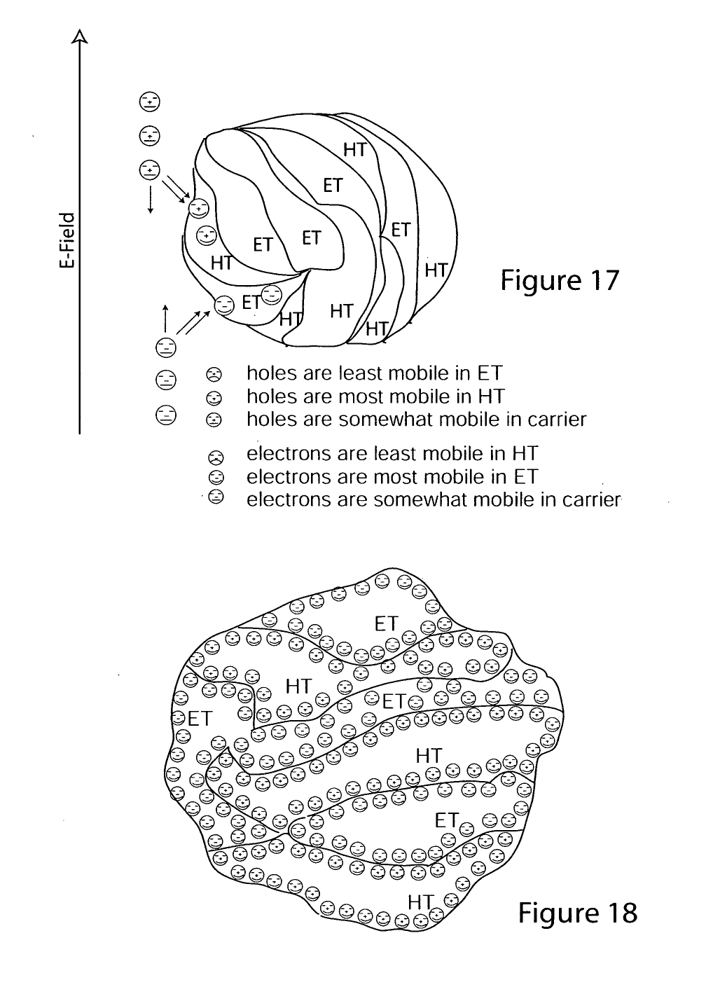

FIG. 17 illustrates a multi-layered OLED particle in an electrical field during the service of a light active electronic device constructed in accordance with the present invention. In accordance with the present invention, an organic light active nano or micro particle is encased within a charge transport carrier. In the case of an energy-to-light device, the charge transport carrier is less conductive of charges than either or both the hole transport material and the electron transport material the comprises the layers of the multi-layered OLED particle. The interfaces between the hole transport and electron transport material are light active sites where photons are emitted by the radiative decay of excitons generated when hole and electron pairs are formed.

As FIG. 17 illustrates, holes are least mobile in the ET material, most mobile in the HT material and somewhat mobile in the carrier material. Electrons, on the other hand, are most mobile in the ET material and somewhat mobile in the carrier material. FIG. 18 illustrates a multi-layered OLED nanoparticle having injected charges migrating toward HT/ET interfaces within the particle. In accordance with the present invention, the charge transport properties of the ET, HT and carrier are selected to encourage a balance of charges and thus improve the efficiency of the light active electronic device. The small volume of the HT and ET layers in the inventive nano-particles creates a quantum confinement effect, wherein charges that enter the layers are repelled by like charges and forced toward the HT/ET interface.

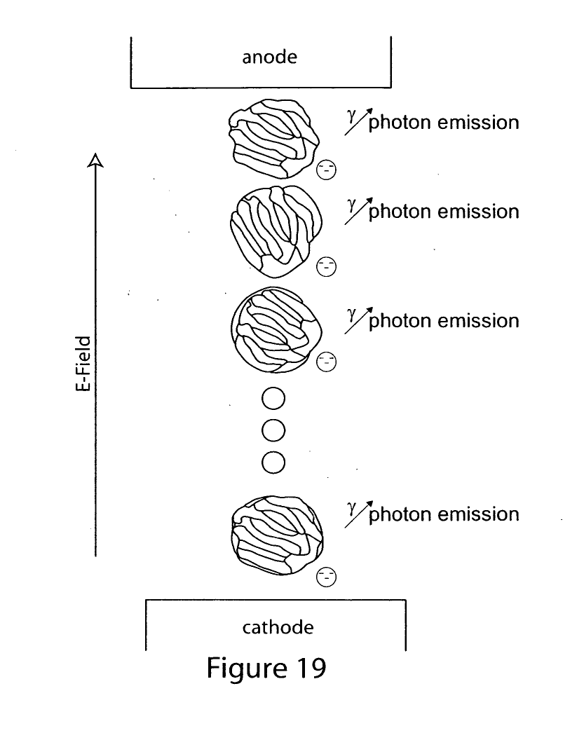

FIG. 19 illustrates a cascading electron efficiency mechanism occurring in a light active electronic device constructed in accordance with the present invention. Charges the are injected into the active layer (carrier and particles) from the anode and cathode are able to combine at the interfaces between the hole transport material and electron transport material in the particles. In accordance with the inventive device structure, a plurality of light active particles are disposed between the anode and cathode. A charge cascading through the active layer may thus result in more than one photon emission because it may combine with its opposite charge multiple times. This mechanism increases the statistical probability of the proper hole/electron pairing that results in photon emission, thus substantially increasing the device efficiency as compared with conventional thin film organic light emitting diode devices.

What is claimed is:

1. A method of making polymer blend light active particles, comprising the steps of:
providing a solution comprised of a first organic light active diode material and a second organic light active diode material in a solvent; providing a non-solvent liquid; and
adding the solution to the non-solvent liquid to cause a precipitation reaction resulting in multi-layered particles comprising the first and second organic light active diode materials.

2. A method of making polymer blend light active particles according to claim 1; wherein the first and second organic light active diode materials are provided in a solvent.

3. A method of making polymer blend light active particles according to claim 1; wherein the first and second organic light active diode material provided in different solvents-streams that are mixed in the non-solvent liquid.

4. A method of making polymer blend light active particles according to claim 1, further including the step of forming nano-particles from said multi-layered particles.

5. A method of making polymer blend light active particles according to claim 4, wherein said nano-particles are formed using a microfluidizer.

6. A method of making a light active electronic device, comprising the steps of:
providing at least one of organic and inorganic light active particles in a non-solvent liquid;
adding a charge transport carrier polymer to the non-solvent liquid to form a fluid carrier/particle mixture; and
disposing the mixture between electrodes to form a light active electronic device.

7. A method of making a light active electronic device according to claim 6, further comprising the steps of:
aligning the particles in the mixture; and
hardening the fluid carrier to secure the alignment of the particles.

8. A method of making a light active electronic device according to claim 6; wherein the charge transport material comprises at least one of an ionic transport material, a conjugated polymer charge transport material and a semi-conductor charge transport material.

9. A method of making a light active electronic device according to claim 6; wherein the particles comprise a multi-layered organic particle comprising hole transport and electron transport layers.

10. A method of making a light active electronic device according to claim 6; wherein the particles comprise an inorganic p/n junction particle further comprising an inorganic LED chip.

11. A method of making a light active electronic device according to claim 6; further comprising the step of hardening the fluid carrier to form a solid-state light active electronic device.
